(19) United States
(12) Patent Application Publication
(10) Pub. No.: US 2026/0291406 A1
(43) Pub. Date: Sep. 24, 2026

(54) APPARATUS AND METHOD FOR COMPENSATING CURRENT SENSOR GAIN ERROR

(71) Applicant: HL MANDO CORPORATION, Gyeonggi-do (KR)

(72) Inventor: Yunjai OH, Gyeonggi-do (KR)

(21) Appl. No.: 19/570,253

(22) Filed: Mar. 18, 2026

(30) Foreign Application Priority Data
Mar. 18, 2025 (KR) 10-2025-0034792

(51) Int. Cl. H02M 7/537; B62D 5/04; G01R 19/10

(52) U.S. Cl. CPC H02M 7/537; B62D 5/046; G01R 19/10

(57) ABSTRACT

The present disclosure relates to a current sensor gain compensation apparatus and method. Specifically, a current sensor gain compensation apparatus according to the present disclosure includes a controller configured to apply a predetermined voltage in an open-loop mode to two phases of a three-phase motor, sensors configured to detect a current of each phase of the three-phase motor, and a compensator configured to determine a current magnitude difference between the two phases, determine a gain compensation coefficient of a current sensor based on the current magnitude difference, and apply the gain compensation coefficient to a gain of any one phase of the two phases.

### CROSS-REFERENCE TO RELATED APPLICATION

This application claims priority from Korean Patent Application No. 10-2025-0034792, filed on Mar. 18, 2025, in the Korean Intellectual Property Office, the disclosure of which is incorporated herein by reference.

### BACKGROUND

### Field

The present embodiments relate to a current sensor gain compensation apparatus and method.

### Description of Related Art

In a general Electric Power Steering (EPS) system, a steering motor may be used to generate a steering assist force to assist a driver's steering force. Such a system supplements the driver's force to facilitate steering of a vehicle and provides better driving stability and convenience.

On the other hand, in the case of a Steer-by-Wire system, a driver's steering force is not directly reflected in the steering of a vehicle in a mechanical manner. Instead, a steering signal of the driver is converted into an electrical signal and transmitted to a steering motor, and the steering of the vehicle is handled only by the torque of the motor. In such a structure, since the performance of the steering motor has a significant influence on determining the steering of the vehicle, the accuracy and efficiency of the motor become more important.

In order to increase the accuracy of a steering motor, the current flowing through the motor must be accurately measured and controlled through a current sensor. The current sensor detects a phase current of the motor in real time and provides a feedback signal to a controller, thereby accurately adjusting the torque of the motor. However, in a system using a current sensor, when there is an error in a gain of the current sensor, a problem may occur in motor control.

If an error occurs in the gain of the current sensor, the magnitude of the phase current flowing through the motor cannot be accurately measured. This causes imbalance in the current required to control the motor, and such imbalance may cause electrical secondary current pulsations. The electrical secondary current pulsations cause pulsation in torque, which deteriorates the performance of the steering system.

Accordingly, a method for compensating for a gain error of a current sensor is required.

### SUMMARY

Against this background, the present disclosure is directed to providing a current sensor gain compensation apparatus and method that perform an open-loop voltage command in a three-phase motor to determine a gain compensation coefficient of a current sensor through a current difference of each phase, and apply the gain compensation coefficient to a gain of any one phase.

To solve the above-described problems, in one aspect, the present disclosure provides a current sensor gain compensation apparatus comprising: a controller configured to set a voltage command to cause two-phase conduction in two phases of a three-phase motor, and apply a predetermined voltage in an open-loop mode based on the voltage command; sensors configured to detect a current of each phase of the three-phase motor; and a compensator configured to determine a current magnitude difference between the two phases, determine a gain compensation coefficient of a current sensor based on the current magnitude difference, and apply the gain compensation coefficient to a gain of any one phase of the two phases.

In another aspect, the present disclosure provides a current sensor gain compensation method comprising: setting a voltage command to cause two-phase conduction in two phases of a three-phase motor, and applying a predetermined voltage in an open-loop mode based on the voltage command; detecting a current of each phase of the three-phase motor; and determining a current magnitude difference between the two phases, determining a gain compensation coefficient of a current sensor based on the current magnitude difference, and applying the gain compensation coefficient to a gain of any one phase of the two phases.

In still another aspect, the present disclosure provides a vehicle control apparatus comprising: at least one memory including computer program instructions; and at least one processor executing the computer program instructions, wherein the at least one processor is configured to: set a voltage command to cause two-phase conduction in two phases of a three-phase motor, apply a predetermined voltage in an open-loop mode based on the voltage command, detect a current of each phase of the three-phase motor, determine a current magnitude difference between the two phases, determine a gain compensation coefficient of a current sensor based on the current magnitude difference, and apply the gain compensation coefficient to a gain of any one phase of the two phases.

According to the present disclosure, a current sensor gain compensation apparatus and method can obtain a gain error component of a current sensor without using a separate mechanical device.

In addition, the present disclosure can compensate for a gain error of a current sensor by utilizing a gain error component of the current sensor.

In addition, the present disclosure can reduce noise and vibration of a mechanical second-order component by compensating for the gain error of the current sensor.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram for briefly explaining a current sensor gain compensation apparatus according to an embodiment of the present disclosure.

FIG. 2 is a block diagram for explaining current gain compensation of a current sensor utilizing an open-loop voltage command according to an embodiment.

FIG. 3 is a view for explaining that induced current occurs upon an open-loop voltage command according to an embodiment.

FIG. 4 is a view showing a result of applying a gain compensation coefficient according to an embodiment.

FIG. 5 is a view showing current flow in a Gating ON Sequence according to an embodiment.

FIG. 6 is a view showing current flow in a Gating OFF Sequence according to an embodiment.

FIG. 7 is a view showing stator magnetic flux after an open-loop voltage command according to an embodiment.

FIG. 8 is a view showing that a position of a rotor has moved in a direction of stator magnetic flux according to an embodiment.

FIG. 9 is a block diagram of a current sensor gain compensation apparatus according to another embodiment of the present disclosure.

FIG. 10 is a flowchart explaining a current sensor gain compensation method according to an embodiment of the present disclosure.

FIG. 11 is a flowchart for explaining applying a gain compensation coefficient at a different angle and in a different phase combination of a three-phase motor according to an embodiment.

### DETAILED DESCRIPTION

Hereinafter, some embodiments of the present disclosure will be described in detail with reference to exemplary drawings. In adding reference numerals to components of each drawing, the same components may have the same numerals as much as possible even if they are displayed on different drawings. In addition, in describing the present embodiments, if it is determined that a detailed description of a related known configuration or function may obscure the gist of the present technical idea, the detailed description may be omitted. When “includes,” “has,” “consists of,” etc., mentioned in the present specification are used, other parts may be added unless “only” is used. In a case where a component is expressed in the singular, a case including the plural may be included unless otherwise explicitly stated.

In addition, in describing the components of the present disclosure, terms such as first, second, A, B, (a), and (b) may be used. These terms are only for distinguishing the component from other components, and the essence, order, sequence, or number of the component is not limited by the term.

In the description of the positional relationship of components, when it is described that two or more components are “connected,” “coupled,” or “joined,” etc., the two or more components may be directly “connected,” “coupled,” or “joined,” but it should be understood that other components may be further “interposed” between the two or more components and the components may be “connected,” “coupled,” or “joined.” Here, the other components may be included in one or more of the two or more components that are “connected,” “coupled,” or “joined” to each other.

In the description of temporal sequence relationships related to components, operation methods, manufacturing methods, etc., for example, when temporal sequence relationships or flow sequence relationships are described as “after,” “subsequent to,” “next to,” “before,” etc., non-continuous cases may also be included unless “immediately” or “directly” is used.

Meanwhile, when numerical values or corresponding information (e.g., level, etc.) for components are mentioned, even if there is no separate explicit description, the numerical values or corresponding information may be interpreted as including an error range that may occur due to various factors (e.g., process factors, internal or external impact, noise, etc.).

Hereinafter, a current sensor gain compensation apparatus of the present disclosure will be described with reference to the accompanying drawings.

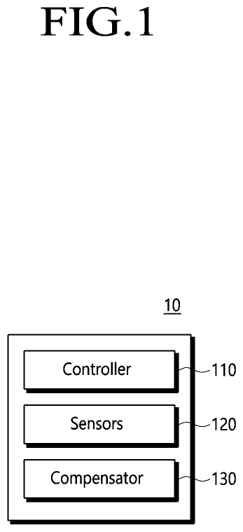

FIG. 1 is a block diagram for briefly explaining a current sensor gain compensation apparatus 10 according to an embodiment of the present disclosure.

Referring to FIG. 1, the current sensor gain compensation apparatus 10 of the present disclosure may include a controller 110, sensors 120, and a compensator 130.

The present disclosure may apply a predetermined voltage in an open-loop mode to cause two-phase conduction in two phases of a three-phase motor, detect a current of each phase of the three-phase motor, calculate a current magnitude difference between the two phases, determine a gain compensation coefficient of a current sensor based on the current magnitude difference, and apply the gain compensation coefficient to a gain of any one phase of the two phases.

In one embodiment, the current sensor gain compensation apparatus 10 may be an advanced driver assistance system (ADAS) that provides information helping driving of a subject vehicle or providing assistance to a driver's control of the subject vehicle.

The controller 110 may cause a predetermined voltage to be applied in an open-loop mode to two phases in the three-phase motor.

In one embodiment, the three-phase motor may be a permanent magnet synchronous motor (PMSM) that has high efficiency and high output characteristics and is capable of precisely controlling rotation speed and torque, or a brushless DC motor (BLDC) that has a structure without a commutator and a brush, has low friction and noise, is easy to maintain, and is driven in a square wave form rather than a sine wave form for a current waveform. However, as long as the technical idea of the present disclosure can be applied substantially identically, the three-phase motor is not limited to a specific type.

In the three-phase motor, the two phases may be any two phases among the three phases constituting the three-phase motor selected randomly, selected according to a predetermined rule, or a phase to which a current sensor is connected may be selected.

The open-loop mode is a control method that does not use feedback control, and unlike a closed-loop method in which the controller 110 adjusts a control signal according to a state (current, speed, position, etc.) of the motor, in the open-loop mode, the controller 110 may apply a predetermined voltage to the motor as it is.

According to an example, the controller 110 may apply a voltage at a predetermined angle by adjusting an open-loop voltage command angle even if the three-phase motor is not at a specific position.

In one embodiment, the predetermined angle may mean, for example, a position where two-phase conduction is possible. Here, the two-phase conduction may mean a state in which a current path through which a current can flow is formed by inverter switching, a voltage command, or the like for two different phases among three phases (U, V, W) of the three-phase motor, for example, a U-phase and a V-phase, such that the two phases participate in current delivery. At this time, the remaining one phase may be controlled to not substantially participate in the current path, for example, in a state corresponding to a voltage command of 0. In the present disclosure, the three phases may be referred to as U, V, W or a, b, c, or may be referred to as a first phase, a second phase, a third phase, and the like.

An angle at which the two-phase conduction occurs may be expressed as in Equation 1 below.

$$θ = \frac{π}{3} \cdot n + \frac{π}{6} , ( n = 1 , 2 , 3 , … ) \qquad [ Equation 1 ]$$

Accordingly, based on 360 degrees, the angles at which the two-phase conduction occurs may be 30 degrees, 90 degrees, 150 degrees, 210 degrees, 270 degrees, and 330 degrees. In this case, at 30 degrees and 210 degrees, 90 degrees and 270 degrees, and 150 degrees and 330 degrees, the voltage applied to the same phase may be 0, respectively. For example, at 30 degrees and 210 degrees, the V-phase is 0V, that is, the U-phase and the W-phase may be in two-phase conduction. Similarly, at 90 degrees and 270 degrees, the W-phase is 0V, that is, the U-phase and the V-phase may be in two-phase conduction. Similarly, at 150 degrees and 330 degrees, the U-phase is 0V, that is, the V-phase and the W-phase may be in two-phase conduction. Accordingly, according to an example, by increasing the angle of the voltage command by 120 degrees, it is possible to detect whether the current sensor is abnormal for each combination of two different phases sequentially at 30 degrees, 150 degrees, and 270 degrees.

The controller 110 may perform the open-loop voltage command by synthesizing voltages at a position where two-phase conduction is possible, and if it is assumed that an offset of the current sensor is corrected, currents of two phases excluding one phase may be detected to have the same magnitude and opposite signs.

Accordingly, the controller 110 may generate the open-loop voltage command so that the three-phase motor is in two-phase conduction, so that a predetermined voltage is applied to two phases and no voltage is applied to the remaining phase.

In addition, the controller 110 may adjust the angle of the open-loop voltage command regardless of a position of the three-phase motor to cause two-phase conduction, that is, to cause a predetermined voltage to be applied to two phases and a voltage of the remaining phase to be 0.

The sensors 120 may detect a current of each phase of the three-phase motor. The sensors 120 may include current sensors connected to at least two phases in the three-phase motor. The sensors 120 may detect a current from each current sensor, and when the current sensors are connected to only two phases, the sensors 120 may detect a current for the remaining phase by utilizing a property that a sum of currents for the three phases is zero. Here, the two current sensors include, for example, a voltage drop type current sensor using a shunt resistor, but is not limited thereto.

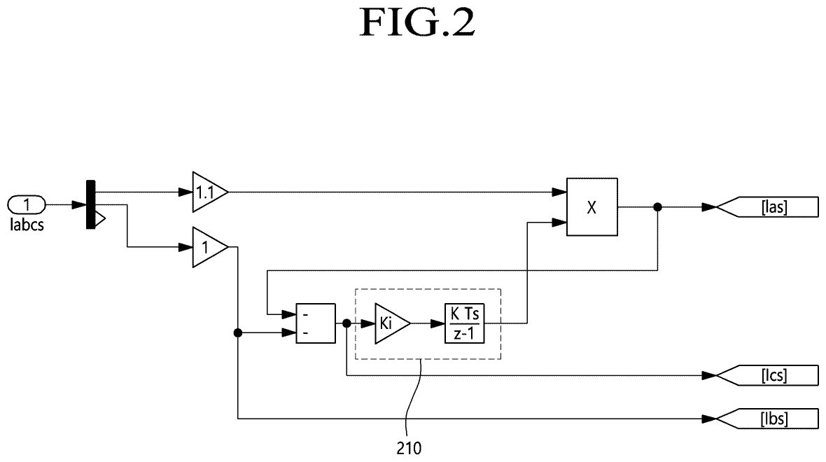

FIG. 2 is a block diagram for explaining current gain compensation of a current sensor using an open-loop voltage command according to an embodiment.

The compensator 130 may calculate a current magnitude difference between two phases, determine a gain compensation coefficient of a current sensor based on the current magnitude difference, and apply the gain compensation coefficient to a gain of any one phase of the two phases.

According to an example, the compensator 130 may identify a current sensor in which an error occurs by comparing a reference current value with a measured value of each current sensor. The reference current value may mean a reference current magnitude theoretically derived based on a voltage applied by the controller 110 and a resistance component of the three-phase motor. The compensator 130 may compare detected currents of the two phases in two-phase conduction with the reference current value, respectively. At this time, the compensator 130 may specify a phase having a larger deviation from the reference current value as a phase to which a faulty current sensor is connected.

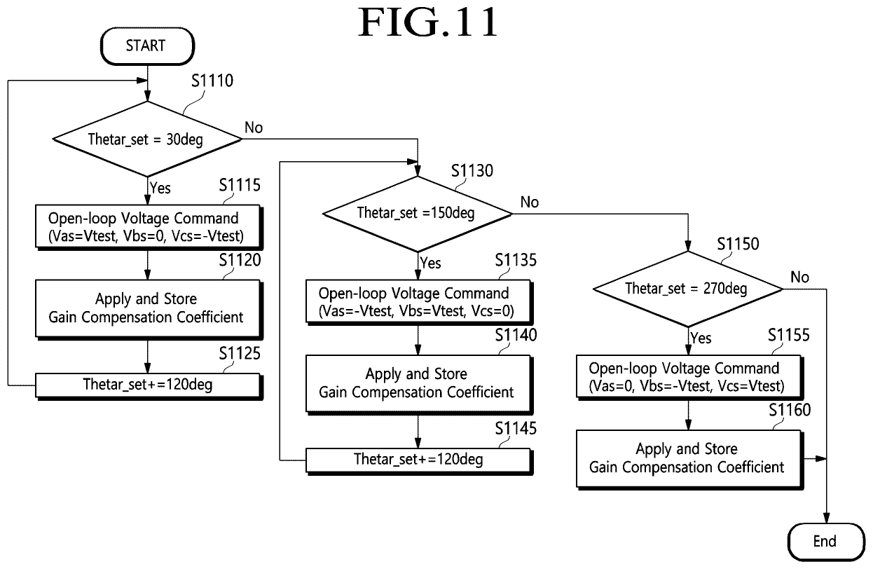

Further, according to an example, cross-validation logic may be performed to determine a phase in which an error occurs by sequentially adding the angles of the voltage command. Referring to FIG. 11, which will be described below, the controller 110 may first test whether a gain error occurs by conducting a first phase and a third phase at a first angle (for example, 30 degrees). Then, the controller 110 may add the angle of the voltage command by 120 degrees, which is the reference angle, to perform a second test by causing two-phase conduction in a combination of phases different from the previous test (for example, the first phase and a second phase) at an angle of 150 degrees. When the current detection process is repeated while changing the phase combination in this way, the compensator 130 can logically derive a specific phase that commonly causes an error. For example, if an error is detected in the combination of the first phase and the third phase and an error is also detected in the subsequent combination of the first phase and the second phase, the compensator 130 may determine that a gain error has occurred in the current sensor of the first phase, which is a common denominator of the two combinations.

Referring to FIG. 2, FIG. 2 shows that current sensors are connected to a first phase (Ias) and a second phase (Ibs), and a gain compensation coefficient is determined and applied by applying a predetermined voltage to the first phase and the second phase.

In one embodiment, the compensator 130 may include an integral controller 210 that receives the current magnitude difference and outputs the gain compensation coefficient. Such a gain compensation coefficient may be applied by being multiplied by the gain of the first phase or the second phase.

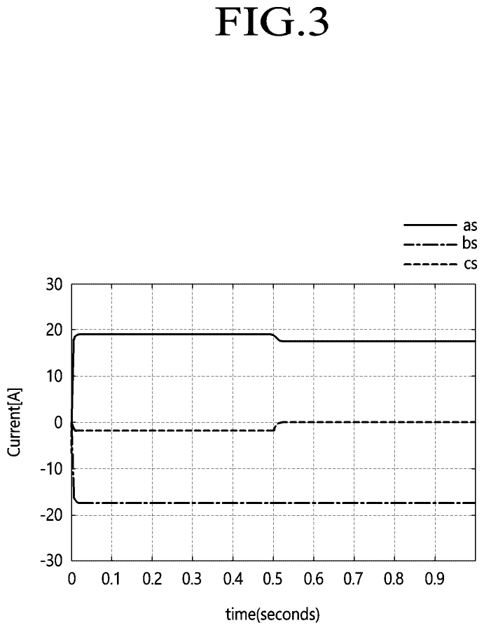

FIG. 3 is a view for explaining that an induced current appears during an open-loop voltage command according to an embodiment.

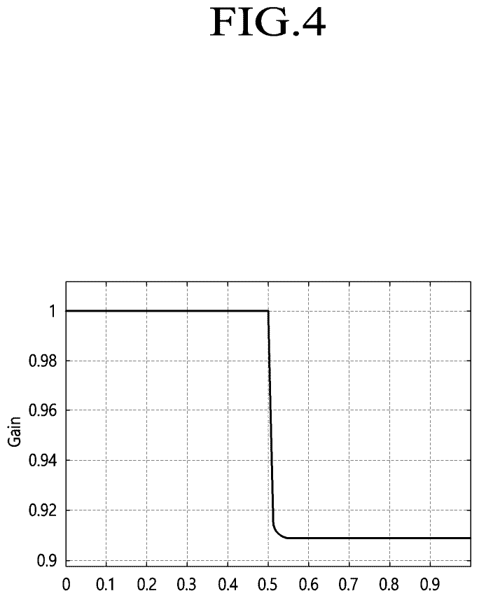

FIG. 4 is a diagram illustrating a result of applying a gain compensation coefficient according to an embodiment.

Referring to FIG. 3, it can be seen that a current magnitude in a first phase and a current magnitude in a second phase are different in results detected by respective current sensors in the first phase and the second phase. As described above, since voltages having the same magnitude and different signs are applied to the first phase and the second phase, the current sensors connected to the respective phases should detect currents of the same magnitude. However, such a difference in current magnitude may be determined as a current sensor gain error having occurred in the current sensor.

Compensator 130 may determine a gain compensation coefficient to compensate for a gain of a current sensor. Compensator 130 may compensate for a gain of any one current sensor, and may set a current sensor having a current calculated according to a predetermined voltage as a reference. For example, when current Ibs of the two phases in FIG. 3 detects a current according to a predetermined voltage, a gain compensation coefficient may be determined so that current Ias of the first phase becomes equal to the current of the second phase. When the gain of the first phase is 1.1 times, compensator 130 may determine the gain compensation coefficient to be 0.9091 so as to be compensated to 1 time, and may multiply the gain of the first phase by the gain compensation coefficient.

Referring to FIG. 4, it can be seen that the gain of the first phase decreases from 0.5 seconds as an output of integral controller 210, and referring to FIG. 3, it can be seen that the current of the first phase and the current of the second phase gradually become equal after 0.5 seconds have passed. In addition, the current of a third phase should also be 0 if no current sensor gain error occurs, but it did not become 0 due to the occurrence of the current sensor gain error, and it can be seen that the current of the third phase is compensated to 0 after 0.5 seconds of compensation has passed.

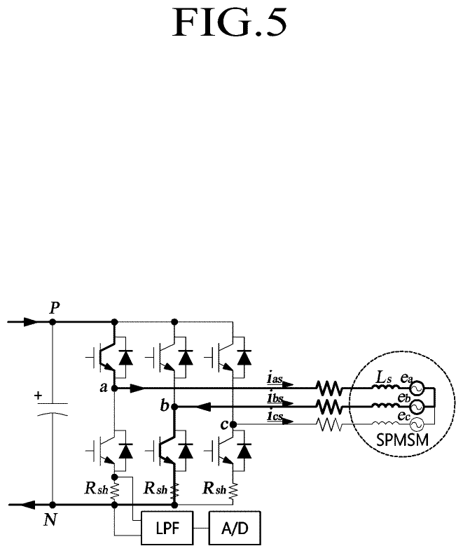

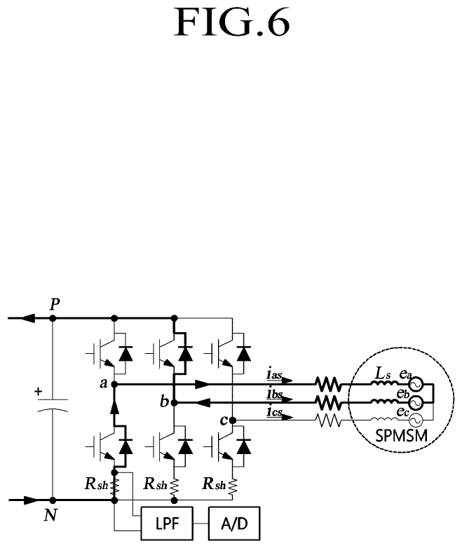

FIG. 5 is a diagram illustrating current flow in a Gating ON Sequence according to an embodiment, and FIG. 6 is a diagram illustrating current flow in a Gating OFF Sequence according to an embodiment.

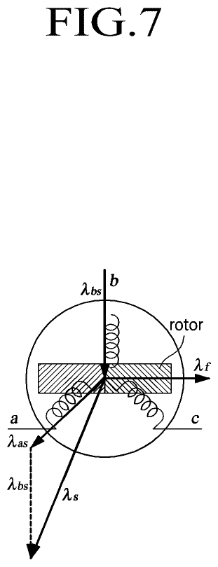

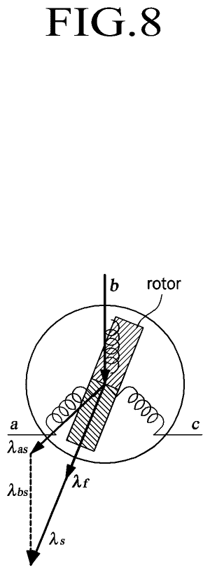

FIG. 7 is a diagram illustrating a stator magnetic flux after an open-loop voltage command according to an embodiment, and FIG. 8 is a diagram illustrating that a position of a rotor has moved in a direction of the stator magnetic flux according to an embodiment.

In an embodiment, when the gain compensation coefficient is determined, an application operation of the gain compensation coefficient may be performed again at an angle obtained by rotating an angle of the voltage command by a reference angle. Here, the reference angle means a preset rotation angle and may be set to 120 degrees according to an example.

Specifically, referring to FIGS. 5 and 6, when open-loop voltage commands for two phases are performed, a sum of voltages for three phases is 0, predetermined currents flow in opposite directions in the two phases for which the open-loop voltage commands are performed, and no current flows in the remaining one phase.

Based on such a phase current relationship, magnetic fluxes of three phases of a stator may be expressed as in Equation 2 below. That is, a sum vector magnetic flux (2s) having a specific magnitude and direction may be fixedly formed in the stator by the voltage command. For example, when phase a and phase b are under two-phase conduction, as in Equation 2, the magnetic fluxes of phase a and phase b are formed with the same magnitude but only different signs, and the magnetic flux of phase c may be 0.

$${λ}_{as} = - {λ}_{bs} , {λ}_{cs} = 0 \qquad [ Equation 2 ]$$

Referring to FIG. 7, at a time when a rotor exists at an arbitrary position and an open-loop voltage is first synthesized, an output torque of a motor may be expressed as in Equation 3 below.

$$\text{?} = \frac{3}{2} \frac{P}{2} {λ}_{f} {λ}_{s} sin ( θ ) \qquad [ Equation 3 ]$$

$$\text{?} \text{indicates text missing or illegible when filed}$$

Here, λ_{f} may mean a magnetic flux of a permanent magnet, λₛ may mean a stator magnetic flux (a sum vector of three-phase magnetic flux vectors), and θ may mean an angle formed between the magnetic flux of the permanent magnet of the rotor and the stator magnetic flux. Due to this angle difference, motor output torque as in Equation 3 may be generated.

Referring to FIG. 8, when a sufficient time (several times a mechanical time constant) passes after the open-loop voltage command, a position of the stator magnetic flux does not change, but the rotor rotates due to the torque component described above, and a rotor magnetic flux component almost coincides with a direction of a stator magnetic flux component. At the moment an angle formed between the two magnetic fluxes becomes 0, no torque is generated, and the rotor no longer rotates.

In addition, the sensors 120 detect a current of each phase of the three-phase motor, and the compensator 130 calculates a current magnitude difference between the two phases, determines a gain compensation coefficient of a current sensor based on the current magnitude difference, and may apply the gain compensation coefficient to a gain of any one phase of the two phases. That is, the compensator 130 may determine whether a gain error of the current sensor occurs at a different angle. Accordingly, the present disclosure may perform additional compensation depending on whether a gain error of the current sensor occurs at a different angle, and accumulation of optimal gain compensation coefficient data for motor angles is possible.

For example, the controller 110 may perform an open-loop voltage command for a position added by the reference angle several times, and the compensator 130 may determine an average of gain compensation coefficients obtained as the open-loop voltage command is performed as a final gain compensation coefficient.

As another example, the compensator 130 may set a plurality of sections based on a plurality of motor angles at which the open-loop voltage command is performed, and set a gain compensation coefficient applied to each section.

The controller 110 may stop gain compensation when the current magnitude difference is equal to or less than a reference value. The controller 110 receives a current magnitude difference result from the compensator 130 and, when the current magnitude difference between the two phases is equal to or less than the reference value, determines that a gain error of the current sensor has not occurred and may determine that an additional open-loop voltage command is unnecessary.

In one embodiment, when the gain compensation coefficient is determined, the controller 110 applies a predetermined voltage in an open-loop mode to a position where the three-phase motor is rotated by the reference angle, and may apply a predetermined voltage to a combination of phases different from the two phases. For example, if the predetermined voltage was initially applied to a first phase and a second phase, the controller 110 may then cause the predetermined voltage to be applied to the first phase and a third phase. That is, as described above, according to an example, when the reference angle is set to 120 degrees, different combinations of two phases may sequentially undergo two-phase conduction according to voltage commands corresponding to 30 degrees, 150 degrees, and 270 degrees.

In addition, the sensors 120 detect a current of each phase of the three-phase motor, and the compensator 130 calculates a current magnitude difference between the first phase and the third phase, determines a gain compensation coefficient of a current sensor based on the current magnitude difference, and may apply the gain compensation coefficient to a gain of the first phase or the third phase.

Accordingly, the present disclosure may apply a predetermined voltage to a combination of phases different from a previous combination and determine whether a gain error of the current sensor occurs accordingly. Specifically, due to characteristics of the three-phase motor, a magnetic field generated by a current of each phase may vary depending on an angle of the motor and a combination of phases. For example, electromagnetic interaction occurring in the rotor of the three-phase motor may differ between a case where a voltage is applied to the first phase and the second phase and a case where a voltage is applied to the second phase and the third phase. As a result, a result different from applying a voltage to the same phase may be obtained.

In addition, it is possible to determine whether the gain error of the current sensor consistently occurs by changing the phase combination and repeating the same current detection process.

The present disclosure may determine occurrence of such cumulative errors of current sensors to specify in which current sensor the gain error occurs.

The compensator 130 may apply the gain compensation coefficient to a gain of a phase to which the current sensor is connected.

Specifically, when the current sensor is connected to only any one phase among the applied two phases, the compensator 130 may apply the gain compensation coefficient to a gain of the phase to which the current sensor is connected.

When current sensors are connected to both of the applied two phases, the compensator 130 may compare a current magnitude difference between a predetermined current and currents detected by each of the current sensors. Then, the compensator 130 may apply the gain compensation coefficient to a gain of a phase to which a current sensor that has detected a largest current magnitude difference value is connected. The predetermined current may be set as a value obtained by a current sensor in a normal state detecting a magnitude of a current flowing through any one phase among the two phases when a predetermined voltage is applied to the two phases in the open-loop mode. According to an example, the compensator 130 may compensate for a gain error by reflecting the gain compensation coefficient in a gain value of the current sensor in which the error occurred.

In addition, when current sensors are connected to both of the applied two phases, the compensator 130 compares a current magnitude difference between a predetermined current and currents detected by each of the current sensors, and may determine each gain compensation coefficient such that a magnitude of the current detected by each current sensor becomes a magnitude of the predetermined current. Here, when the current magnitude difference between the detected current and the predetermined current is equal to or less than a reference value, the compensator may not apply the gain compensation coefficient.

Accordingly, the present disclosure may apply a gain compensation coefficient to a current sensor in which a gain error occurs.

In addition, the present disclosure may apply the gain compensation coefficient even when a gain error occurs in a plurality of current sensors by comparing a predetermined current and a current of the current sensor.

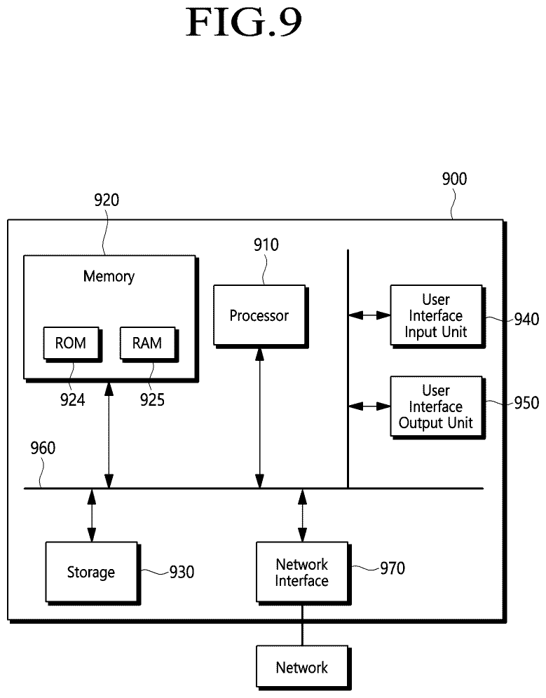

FIG. 9 is a block diagram of a current sensor gain compensation apparatus 10 according to another embodiment of the present disclosure.

In one embodiment, current sensor gain compensation apparatus 10 may be implemented as an electronic control unit (ECU). Referring to FIG. 9, a computer system 900, such as current sensor gain compensation apparatus 10, may include at least one element among one or more processors 910, memory 920, storage 930, user interface input unit 940, and user interface output unit 950, which may communicate with each other through a bus 960. In addition, computer system 900 may also include a network interface 970 for connecting to a network. Processor 910 may be a CPU or a semiconductor device that executes processing instructions stored in memory 920 and/or storage 930. Memory 920 and storage 930 may include various types of volatile/non-volatile storage media. For example, the memory may include ROM 924 and RAM 925.

Hereinafter, a current sensor gain compensation method using current sensor gain compensation apparatus 10 capable of performing all of the above-described disclosure will be described. The above descriptions may be omitted to avoid redundant description, in which case the omitted contents may be substantially identically applied to the following description as long as they do not contradict the technical spirit of the invention.

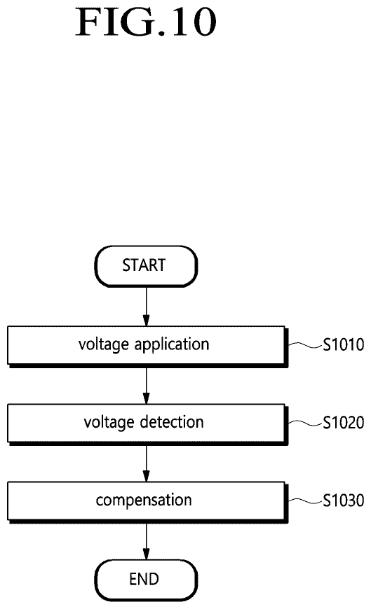

FIG. 10 is a flowchart illustrating a current sensor gain compensation method according to an embodiment of the disclosure.

Referring to FIG. 10, a current sensor gain compensation method according to an embodiment of the disclosure may include a voltage applying step (S1010) of setting a voltage command to cause two-phase conduction in two phases of a three-phase motor and applying a predetermined voltage in an open-loop mode based on the voltage command, a current detecting step (S1020) of detecting a current of each phase of the three-phase motor, and a compensating step (S130) of calculating a current magnitude difference between the two phases, determining a gain compensation coefficient of a current sensor based on the current magnitude difference, and applying the gain compensation coefficient to a gain of any one phase of the two phases.

When the gain compensation coefficient is determined, a predetermined voltage may be applied to two phases in the open-loop mode at an angle obtained by rotating an angle of the voltage command by a reference angle. As the voltage is applied to two phases of the rotated three-phase motor, the current sensor gain compensation apparatus detects the current of each phase of the three-phase motor at a different angle, and the current sensor gain compensation apparatus may apply the gain compensation coefficient determined at the different angle to any one phase. That is, when the gain compensation coefficient is determined, an application operation of the gain compensation coefficient may be performed again at an angle obtained by rotating the angle of the voltage command by the reference angle.

The current sensor gain compensation apparatus may stop application of the gain compensation coefficient when the current magnitude difference is equal to or less than a reference value. When the current magnitude difference is equal to or less than the reference value, the current sensor gain compensation apparatus may determine that a gain error has not occurred in the current sensor.

The current sensor gain compensation apparatus may apply a predetermined voltage to cause two-phase conduction in a combination of two phases different from the two phases. In addition, the present disclosure may determine whether a gain error of the current sensor occurs at a different combination of two phases and at a different angle by performing the aforementioned current detecting step (S1020) and compensating step (S1030).

The current sensor gain compensation apparatus may receive the current magnitude difference and output the gain compensation coefficient through an integral controller. Accordingly, the present disclosure may obtain a gain error component without a separate mechanical device.

The current sensor gain compensation apparatus may apply a voltage at a predetermined angle causing two-phase conduction.

The current sensor gain compensation apparatus may apply the gain compensation coefficient to a gain of a phase to which the current sensor is connected.

FIG. 11 is a flowchart for explaining applying a gain compensation coefficient at a different angle and a different phase combination of a three-phase motor according to an embodiment.

Referring to FIG. 11, current sensor gain compensation apparatus 10 may determine whether an angle setting of a voltage command for a three-phase motor is 30 degrees (S1110). For example, current sensor gain compensation apparatus 10 may cause a voltage to be applied in an open-loop mode to two phases even if the three-phase motor is not at a specific position. Alternatively, a voltage may be applied in an open-loop mode to two phases when the three-phase motor is positioned at a predetermined angle. In this case, current sensor gain compensation apparatus 10 may receive a position of the three-phase motor from a motor position sensor (MPS).

When the angle setting of the voltage command for the three-phase motor is 30 degrees (Yes in S1110), current sensor gain compensation apparatus 10 may perform an open-loop voltage command so that two phases are in two-phase conduction (S1115). For example, current sensor gain compensation apparatus 10 may apply a predetermined voltage (Vtest) to a first phase and a third phase.

Current sensor gain compensation apparatus 10 may calculate a current detected in each phase to determine whether a gain error occurs in the current sensor, determine a gain compensation coefficient for gain compensation, apply the gain compensation coefficient by multiplying it with a gain of any one phase, and store the gain compensation coefficient (S1120).

As described above, an output torque of the three-phase motor is generated according to the open-loop voltage command, and the angle setting of the voltage command may be set to a value added by 120 deg, which is a reference angle (S1125).

When the angle setting of the voltage command for the three-phase motor is not 30 degrees (No in S1110), current sensor gain compensation apparatus 10 may determine whether the angle setting of the voltage command for the three-phase motor is 150 degrees (S1130). That is, it may be determined whether two-phase conduction occurs corresponding to 150 degrees added by 120.

When an angle setting of a voltage command for a three-phase motor is 150 degrees (Yes in S1130), a current sensor gain compensation apparatus 10 may perform an open-loop voltage command such that two phases are in two-phase conduction (S1135). Here, the current sensor gain compensation apparatus 10 may apply a predetermined voltage in an open-loop mode to two phases configured in a combination different from the combination of the two phases of step S1115. For example, the current sensor gain compensation apparatus 10 may apply a predetermined voltage (Vtest) to a first phase and a second phase.

The current sensor gain compensation apparatus 10 may calculate a current detected in each phase to determine whether a gain error of a current sensor occurs, determine a gain compensation coefficient for gain compensation, and apply and store the gain compensation coefficient by multiplying a gain of any one phase by the gain compensation coefficient (S1140).

A setting of an angle of the voltage command may be set to a value added by 120 deg, which is a reference angle (S1145).

When the angle setting of the voltage command for the three-phase motor is not 150 degrees (No in S1130), the current sensor gain compensation apparatus 10 may determine whether the angle of the voltage command for the three-phase motor is 270 degrees (S1150).

When the angle setting of the voltage command for the three-phase motor is 270 degrees (Yes in S1150), the current sensor gain compensation apparatus 10 may perform an open-loop voltage command on two phases (S1155). Here, the current sensor gain compensation apparatus 10 may apply a predetermined voltage in an open-loop mode to two phases configured in a combination different from the combinations of the two phases of step S1115 and step S1135. For example, the current sensor gain compensation apparatus 10 may apply a predetermined voltage (Vtest) to a second phase and a third phase.

The current sensor gain compensation apparatus 10 may calculate a current detected in each phase to determine whether a gain error of a current sensor occurs, determine a gain compensation coefficient for gain compensation, and apply and store the gain compensation coefficient by multiplying a gain of any one phase by the gain compensation coefficient (S1160).

According to the above, the present disclosure may apply a voltage to different combinations of phases at different angles of a three-phase motor to determine whether a gain error of a current sensor occurs in different situations and compensate for the gain error.

In addition, the present disclosure may determine a more accurate gain compensation coefficient by determining and storing whether a gain error occurs in different situations.

In a current sensor, when a gain error occurs during a process of detecting a current of a motor, current pulsation of an electrical secondary component occurs.

Such current pulsation due to the gain error of the current sensor is one of dominant factors causing electrical secondary torque ripple when driving the motor. Torque ripple of the electrical secondary component may cause vibration and noise of a load system and degrade performance of the system.

In this situation, as described above, a current sensor gain compensation apparatus and method may obtain a gain error component of a current sensor without using a separate mechanical device.

In addition, the present disclosure may reduce current pulsation caused by a gain error of a current sensor by compensating for the gain error of the current sensor using a gain error component of the current sensor.

Meanwhile, a current sensor gain compensation apparatus and method according to the present disclosure may be implemented by a vehicle control apparatus.

For example, a vehicle control apparatus may include at least one memory including computer program instructions and at least one processor executing the computer program instructions. The vehicle control apparatus may be an electronic control device including a semiconductor element such as an ECU or an MCU.

Here, the at least one processor may set a voltage command to cause two-phase conduction in two phases of a three-phase motor, apply a predetermined voltage in an open-loop mode based on the voltage command, detect a current of each phase of the three-phase motor, calculate a current magnitude difference between the two phases, determine a gain compensation coefficient of a current sensor based on the current magnitude difference, and apply the gain compensation coefficient to a gain of any one phase of the two phases.

In addition, when the gain compensation coefficient is determined, the at least one processor may perform an application operation of the gain compensation coefficient again at an angle obtained by rotating an angle of the voltage command by a reference angle.

In addition, the at least one processor may stop application of the gain compensation coefficient when the current magnitude difference is equal to or less than a reference value.

In addition, the at least one processor may apply a predetermined voltage to cause two-phase conduction in a combination of two phases different from the combination of the two phases.

In addition, the at least one processor may receive the current magnitude difference and output the gain compensation coefficient through an integral controller.

In addition, the at least one processor may apply a voltage at a predetermined angle causing two-phase conduction.

In addition, the at least one processor may apply the gain compensation coefficient to a gain of a phase to which the current sensor is connected.

The above description is merely an illustrative description of the technical idea of the present disclosure, and those skilled in the art to which the present disclosure pertains will be able to make various modifications and variations without departing from the essential characteristics of the present technical idea. In addition, the embodiments of the present disclosure are not intended to limit the technical idea of the present disclosure but to explain it, and thus the scope of the technical idea of the present disclosure is not limited by these embodiments. The protection scope of the present disclosure should be interpreted by the following claims, and all technical ideas within the equivalent range should be interpreted as being included in the scope of rights of the present disclosure.

What is claimed is:

1. A current sensor gain compensation apparatus comprising:
a controller configured to set a voltage command to cause two-phase conduction in two phases of a three-phase motor, and apply a predetermined voltage in an open-loop mode based on the voltage command;
sensors configured to detect a current of each phase of the three-phase motor; and
a compensator configured to determine a current magnitude difference between the two phases, determine a gain compensation coefficient of a current sensor based on the current magnitude difference, and apply the gain compensation coefficient to a gain of any one phase of the two phases.

2. The current sensor gain compensation apparatus of claim 1, wherein when the gain compensation coefficient is determined, an application operation of the gain compensation coefficient is performed again at an angle obtained by rotating an angle of the voltage command by a reference angle.

3. The current sensor gain compensation apparatus of claim 2, wherein the controller stops application of the gain compensation coefficient when the current magnitude difference is equal to or less than a reference value.

4. The current sensor gain compensation apparatus of claim 2, wherein the controller applies the predetermined voltage to cause two-phase conduction in a combination of two phases different from the combination of the two phases.

5. The current sensor gain compensation apparatus of claim 1, wherein the compensator comprises an integral controller configured to receive the current magnitude difference and output the gain compensation coefficient.

6. The current sensor gain compensation apparatus of claim 1, wherein the controller applies a voltage at a predetermined angle causing two-phase conduction.

7. The current sensor gain compensation apparatus of claim 1, wherein the compensator applies the gain compensation coefficient to a gain of a phase to which the current sensor is connected.

8. A current sensor gain compensation method comprising:
setting a voltage command to cause two-phase conduction in two phases of a three-phase motor, and applying a predetermined voltage in an open-loop mode based on the voltage command;
detecting a current of each phase of the three-phase motor; and
determining a current magnitude difference between the two phases, determining a gain compensation coefficient of a current sensor based on the current magnitude difference, and applying the gain compensation coefficient to a gain of any one phase of the two phases.

9. The current sensor gain compensation method of claim 8, wherein when the gain compensation coefficient is determined, an application operation of the gain compensation coefficient is performed again at an angle obtained by rotating an angle of the voltage command by a reference angle.

10. The current sensor gain compensation method of claim 9, wherein the setting comprises:
stopping application of the gain compensation coefficient when the current magnitude difference is equal to or less than a reference value.

11. The current sensor gain compensation method of claim 9, wherein the setting comprises:
applying the predetermined voltage to cause two-phase conduction in a combination of two phases different from the combination of the two phases.

12. The current sensor gain compensation method of claim 8, wherein the determining comprises:
receiving the current magnitude difference and outputting the gain compensation coefficient through an integral controller.

13. The current sensor gain compensation method of claim 8, wherein the setting comprises:
applying a voltage at a predetermined angle causing two-phase conduction.

14. The current sensor gain compensation method of claim 8, wherein the determining comprises:
applying the gain compensation coefficient to a gain of a phase to which the current sensor is connected.

15. A vehicle control apparatus comprising:
at least one memory including computer program instructions; and
at least one processor executing the computer program instructions,
wherein the at least one processor is configured to:
set a voltage command to cause two-phase conduction in two phases of a three-phase motor, apply a predetermined voltage in an open-loop mode based on the voltage command, detect a current of each phase of the three-phase motor, determine a current magnitude difference between the two phases, determine a gain compensation coefficient of a current sensor based on the current magnitude difference, and apply the gain compensation coefficient to a gain of any one phase of the two phases.

16. The vehicle control apparatus of claim 15, wherein when the gain compensation coefficient is determined, an application operation of the gain compensation coefficient is performed again at an angle obtained by rotating an angle of the voltage command by a reference angle.

17. The vehicle control apparatus of claim 16, wherein the at least one processor stops application of the gain compensation coefficient when the current magnitude difference is equal to or less than a reference value.

18. The vehicle control apparatus of claim 16, wherein the at least one processor applies the predetermined voltage to cause two-phase conduction in a combination of two phases different from the combination of the two phases.

19. The vehicle control apparatus of claim 15, wherein the at least one processor comprises an integral controller configured to receive the current magnitude difference and output the gain compensation coefficient.

20. The vehicle control apparatus of claim 15, wherein the at least one processor applies a voltage at a predetermined angle causing two-phase conduction.
